(19) United States
(12) Patent Application Publication
(10) Pub. No.: US 2026/0255656 A1
(43) Pub. Date: Aug. 27, 2026

(54) PLACEHOLDER AND ITS HEIGHT VARIATION CONTROL

(71) Applicant: INTERNATIONAL BUSINESS MACHINES CORPORATION, Armonk, NY (US)

(72) Inventors: Kamal Rudra, Albany, NY (US); Ruilong Xie, Niskayuna, NY (US); Thanh Nguyen, Troy, NY (US); Shay Reboh, Albany, NY (US); Tao Li, Slingerlands, NY (US); Minhaz Abedin, Delmar, NY (US); Kisik Choi, Watervliet, NY (US); Ravikumar Ramachandran, Pleasantville, NY (US)

(21) Appl. No.: 19/061,385

(22) Filed: Feb. 24, 2025

(51) Int. Cl. H10D 84/01; H10D 84/83

(52) U.S. Cl. CPC H10D 84/0149; H10D 84/013; H10D 84/832

(57) ABSTRACT

Embodiments of present invention provide a method of forming a semiconductor structure. The method includes forming a set of transistors on top of a substrate; creating source/drain (S/D) recesses between the set of transistors; creating one or more placeholder recesses, through one or more of the S/D recesses, in the substrate; forming one or more placeholders in the one or more placeholder recesses with a first dielectric material; epitaxially growing S/D regions in the S/D recesses; replacing the substrate with a backside interlevel dielectric (BILD) layer of a second dielectric material that is different from the first dielectric material, with the BILD layer surrounding the one or more placeholders; and replacing the one or more placeholders with one or more backside contacts. A structure formed thereby is also provided.

### BACKGROUND

The present application relates to manufacturing of semiconductor integrated circuits. More particularly, it relates to forming placeholders for backside contacts of transistors and the structure formed thereby.

As semiconductor industry advances towards ever smaller node or transistor cell, field-effect-transistors (FETs), for example, are aggressively scaled to fit into reduced footprint or real estate thereby the overall device density may be further increased. As part of the on-going effort, some contacts to transistors are being moved from the frontside to the backside of the transistors to become backside contacts, as they are commonly referred to, which further enhance the device density.

Generally, in order to form backside contacts, placeholders are usually first formed in the substrate during the frontside processing. The placeholders are then accessed from the backside of the substrate or device and replaced with backside contacts. In forming the placeholders, recesses are first formed in source/drain regions of transistors and openings are then made, through the recesses, in the substrate below the source/drain regions. However, with the ever shrinking gate-pitch such as when gate-pitch becomes less than 48 nm, the process of forming placeholders from the frontside may be interfered or affected by other frontside processes. For example, openings created for the placeholders may be affected by pinch-off of liners where the liners are used to protect end surfaces of nanosheets.

### SUMMARY

Embodiments of present invention provide a method of forming a semiconductor structure. The method includes forming a set of nanosheet transistors on top of a substrate with each of the set of nanosheet transistors having a set of nanosheets; creating source/drain (S/D) recesses between the set of nanosheet transistors to expose sidewalls of the set of nanosheets; creating one or more placeholder recesses, through one or more of the S/D recesses, in the substrate; forming one or more placeholders in the one or more placeholder recesses with a first dielectric material; epitaxially growing S/D regions in the S/D recesses; replacing the substrate with a backside interlevel dielectric (BILD) layer of a second dielectric material, the BILD layer surrounding the one or more placeholders; and replacing the one or more placeholders with one or more backside contacts.

In one embodiment, forming the one or more placeholders includes depositing the first dielectric material in the one or more placeholder recesses, in the S/D recesses, and on top of the set of nanosheet transistors to form a first dielectric layer, the first dielectric layer in direct contact with the sidewalls of the set of nanosheets; planarizing the first dielectric layer; and recessing the first dielectric layer between the set of nanosheet transistors to form the one or more placeholders.

In another embodiment, forming the one or more placeholders further includes recessing the first dielectric layer until a top surface of the first dielectric layer is below a second nanosheet from a bottom of the set of nanosheets.

In a further embodiment, recessing the first dielectric layer causes a portion of the first dielectric material remaining directly on top of the substrate without any of the one or more placeholder recesses underneath thereof.

In one embodiment, creating the one or more placeholder recesses includes performing a selective etch process to etch the substrate through the one or more of the S/D recesses while rest of the S/D recesses are protected from the selective etch process.

In another embodiment, replacing the one or more placeholders includes selectively etching the first dielectric material, relative to the second dielectric material, to remove the one or more placeholders until one or more of the S/D regions above the one or more placeholders are exposed; and filling spaces left by the selectively etching the first dielectric material with a conductive material to form the one or more backside contacts, where the first dielectric material is different from the second dielectric material in etch selectivity.

In one embodiment, replacing the substrate includes selectively removing the substrate, relative to the first dielectric material of the one or more placeholders, until gate metal of the set of nanosheet transistors are exposed; and selectively etching the first dielectric material, relative to the gate metal of the set of nanosheet transistors, until a bottom surface of at least one of the S/D regions is exposed.

In another embodiment, replacing the substrate further includes selectively etching the exposed gate metal of the set of nanosheet transistors, relative to the exposed at least one of the S/D regions, until a bottom nanosheet of the set of nanosheets is exposed; selectively removing the bottom nanosheet; and depositing the second dielectric material to form the BILD layer to surround the one or more placeholders.

Embodiments of present invention further provide a semiconductor structure. The semiconductor structure includes a set of nanosheet transistors on top of a substrate, each of the set of nanosheet transistors having a set of nanosheets, a metal gate surrounding the set of nanosheets, and source/drain regions at sidewalls of the set of nanosheets; one or more backside contacts underneath one or more of the source/drain regions of the set of nanosheet transistors, the backside contacts being surrounded by a backside interlevel dielectric (BILD) layer of a second dielectric material; and a first dielectric layer of a first dielectric material between one of the source/drain regions of the set of nanosheet transistors and the BILD layer, the first dielectric material being different from the second dielectric material.

In one embodiment, one or more of the source/drain regions have a bottom surface that is below a bottom surface of the metal gate and wherein one of the one or more backside contacts has a top surface that is above the bottom surface of the metal gate.

In another embodiment, one or more of the source/drain regions have a bottom surface that is above a bottom surface of the metal gate and wherein one of the one or more backside contacts has a top surface that is below the bottom surface of the metal gate.

### BRIEF DESCRIPTION OF THE DRAWINGS

The present invention will be understood and appreciated more fully from the following detailed description of embodiments of present invention, taken in conjunction with accompanying drawings of which:

FIGS. 1A and 1B are demonstrative illustrations of different cross-sectional views of a semiconductor structure at a step of manufacturing thereof according to one embodiment of present invention;

FIGS. 2A and 2B are demonstrative illustrations of different cross-sectional views of a semiconductor structure at a step of manufacturing thereof, following the step illustrated in FIGS. 1A and 1B, according to one embodiment of present invention;

FIGS. 3A and 3B are demonstrative illustrations of different cross-sectional views of a semiconductor structure at a step of manufacturing thereof, following the step illustrated in FIGS. 2A and 2B, according to one embodiment of present invention;

FIGS. 4A and 4B are demonstrative illustrations of different cross-sectional views of a semiconductor structure at a step of manufacturing thereof, following the step illustrated in FIGS. 3A and 3B, according to one embodiment of present invention;

FIGS. 5A and 5B are demonstrative illustrations of different cross-sectional views of a semiconductor structure at a step of manufacturing thereof, following the step illustrated in FIGS. 4A and 4B, according to one embodiment of present invention;

FIGS. 6A and 6B are demonstrative illustrations of different cross-sectional views of a semiconductor structure at a step of manufacturing thereof, following the step illustrated in FIGS. 5A and 5B, according to one embodiment of present invention;

FIGS. 7A and 7B are demonstrative illustrations of different cross-sectional views of a semiconductor structure at a step of manufacturing thereof, following the step illustrated in FIGS. 6A and 6B, according to one embodiment of present invention;

FIGS. 8A and 8B are demonstrative illustrations of different cross-sectional views of a semiconductor structure at a step of manufacturing thereof, following the step illustrated in FIGS. 7A and 7B, according to one embodiment of present invention;

FIGS. 9A and 9B are demonstrative illustrations of different cross-sectional views of a semiconductor structure at a step of manufacturing thereof, following the step illustrated in FIGS. 8A and 8B, according to one embodiment of present invention;

FIGS. 10A and 10B are demonstrative illustrations of different cross-sectional views of a semiconductor structure at a step of manufacturing thereof, following the step illustrated in FIGS. 9A and 9B, according to one embodiment of present invention;

FIGS. 11A and 11B are demonstrative illustrations of different cross-sectional views of a semiconductor structure at a step of manufacturing thereof, following the step illustrated in FIGS. 10A and 10B, according to one embodiment of present invention;

FIGS. 12A and 12B are demonstrative illustrations of different cross-sectional views of a semiconductor structure at a step of manufacturing thereof, following the step illustrated in FIGS. 11A and 11B, according to one embodiment of present invention;

FIGS. 13A and 13B are demonstrative illustrations of different cross-sectional views of a semiconductor structure at a step of manufacturing thereof, following the step illustrated in FIGS. 12A and 12B, according to one embodiment of present invention;

FIGS. 14A and 14B are demonstrative illustrations of different cross-sectional views of a semiconductor structure at a step of manufacturing thereof, following the step illustrated in FIGS. 13A and 13B, according to one embodiment of present invention;

FIGS. 15A and 15B are demonstrative illustrations of different cross-sectional views of a semiconductor structure at a step of manufacturing thereof, following the step illustrated in FIGS. 14A and 14B, according to one embodiment of present invention;

FIGS. 16A and 16B are demonstrative illustrations of different cross-sectional views of a semiconductor structure at a step of manufacturing thereof, following the step illustrated in FIGS. 15A and 15B, according to one embodiment of present invention;

FIGS. 17A and 17B are demonstrative illustrations of different cross-sectional views of a semiconductor structure at a step of manufacturing thereof, following the step illustrated in FIGS. 16A and 16B, according to one embodiment of present invention; and

FIG. 18 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

To provide spatial context to different structural orientations of the semiconductor structures shown in the drawings, XYZ Cartesian coordinates may be provided in some of the drawings. The terms “vertical” or “vertical direction” or “vertical height” as used herein denote a Z-direction of the Cartesian coordinates shown in the drawings, and the terms “horizontal” or “horizontal direction” or “lateral direction” as used herein denote an X-direction and/or a Y-direction of the Cartesian coordinates shown in the drawings.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

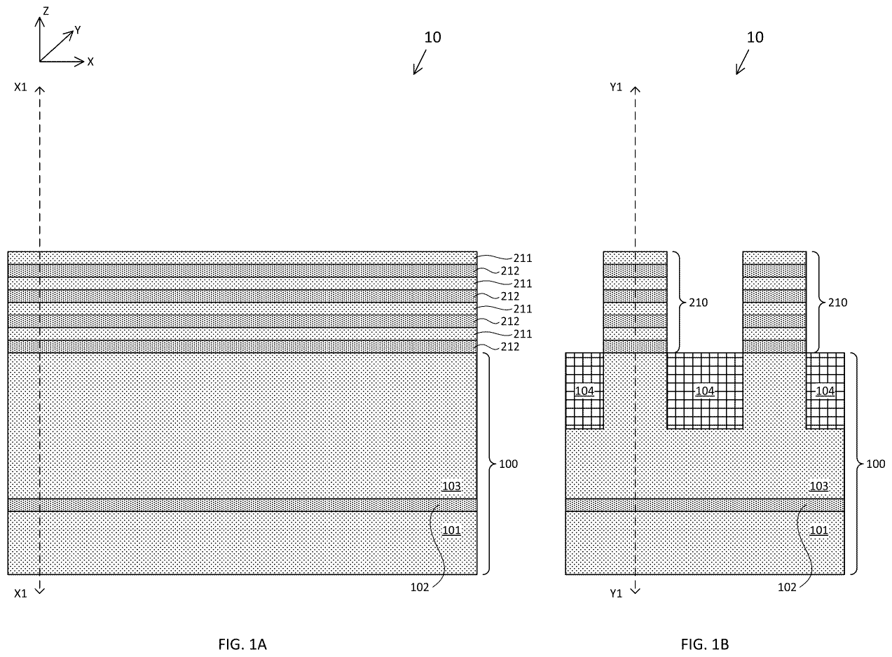

FIGS. 1A and 1B are demonstrative illustrations of different cross-sectional views of a semiconductor structure at a step of manufacturing thereof according to one embodiment of present invention. More specifically, FIG. 1A demonstratively illustrates a cross-sectional view of a semiconductor structure 10 with a cross-section made along a dashed line Y1-Y1 as being indicated in FIG. 1B. In other words, the cross-section shown in FIG. 1A is made across gates of transistors (to be formed later) in a direction along a width of the gates of the transistors. FIG. 1B demonstratively illustrates a cross-sectional view of the semiconductor structure 10 with a cross-section made along a dashed line X1-X1 as being indicated in FIG. 1A. In other words, the cross-section shown in FIG. 1B is made across the gates of the transistors in a direction along a length of the gates of the transistors.

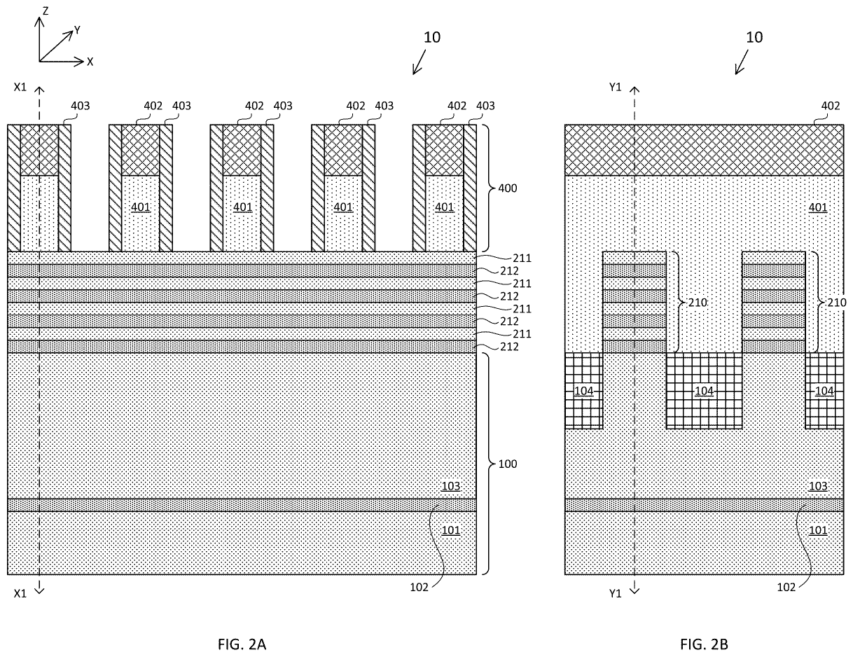

Likewise, FIGS. 2A and 2B to FIGS. 17A and 17B are demonstrative cross-sectional views of the semiconductor structure 10 at cross-sections made across the gates of the transistors along the width and the length respectively, at various manufacturing steps, in manners similar to FIGS. 1A and 1B respectively.

Referring back to FIGS. 1A and 1B, embodiments of present invention provide receiving or providing a semiconductor substrate 100 and forming a set of transistors by forming one or more stacks of nanosheets 210 on top of the semiconductor substrate 100. The semiconductor substrate 100 may be a bulk silicon (Si) substrate, a bulk germanium (Ge) substrate, a silicon-germanium (SiGe) substrate, a silicon-on-insulator (SOI) substrate, a silicon-germanium-on-insulator (SGOI), and/or other suitable substrate. As is illustrated in FIGS. 1A and 1B, the semiconductor substrate 100 may be a SOI substrate that includes a bulk Si substrate 101, a dielectric layer 102 on top of the bulk Si substrate 101, and a Si layer 103 on top of the dielectric layer 102. During subsequent manufacturing processes, the dielectric layer 102 may work or function as an etch-stop layer (ESL). For that reason, the dielectric layer 102 may be referred to as an ESL as well.

The one or more stacks of nanosheets 210 may each include a set of Si nanosheets 211 stacked together, alternately, with a set of sacrificial layers 212. The set of sacrificial layers 212 may be a set of SiGe layers and may have an etch selectivity that is different from the set of Si nanosheets 211. One or more shallow-trench-isolation (STI) layers 104 may be formed in the Si layer 103 of the semiconductor substrate 100, and the STI layers 104 may be formed in between the one or more stacks of nanosheets 210, providing insulation among the one or more stacks of nanosheets 210.

FIGS. 2A and 2B are demonstrative illustrations of different cross-sectional views of a semiconductor structure at a step of manufacturing thereof, following the step illustrated in FIGS. 1A and 1B, according to one embodiment of present invention. More particularly, embodiments of present invention provide forming a set of sacrificial gate structures 400 on top of the one or more stacks of nanosheets 210. The set of sacrificial gate structures 400 may each include a sacrificial gate 401, a capping layer 402 on top of the sacrificial gate 401, and sidewall spacers 403 at sidewalls of the sacrificial gate 401 and the capping layer 402. The sacrificial gate 401 may include, or be made of, polysilicon (Poly-Si) material for example, the capping layer 402 and sidewall spacers 403 may include, or be made of, dielectric material such as, for example, silicon-nitride (SiN), silicon-oxide (SiOx), and/or other suitable materials. The capping layer 402 and the sidewall spacers 403 may be made of same or different dielectric materials.

The set of sacrificial gate structures 400 may be made by, for example, depositing a layer of polysilicon or other material suitable for forming the sacrificial gates 401 on top of and covering the one or more stacks of nanosheets 210, and subsequently patterning the layer of polysilicon material, through a lithographic patterning and etch process, into the sacrificial gates 401 with the capping layers 402 on top of and covering the sacrificial gates 401. Next, a conformal dielectric layer may be deposited on top of the sacrificial gates 401 and the capping layers 402. The conformal dielectric layer may be etched, through an anisotropic and/or directional etch process such as a reactive-ion-etch (RIE) process, to form the sidewall spacers 403 at sidewalls of the sacrificial gates 401 and the capping layers 402.

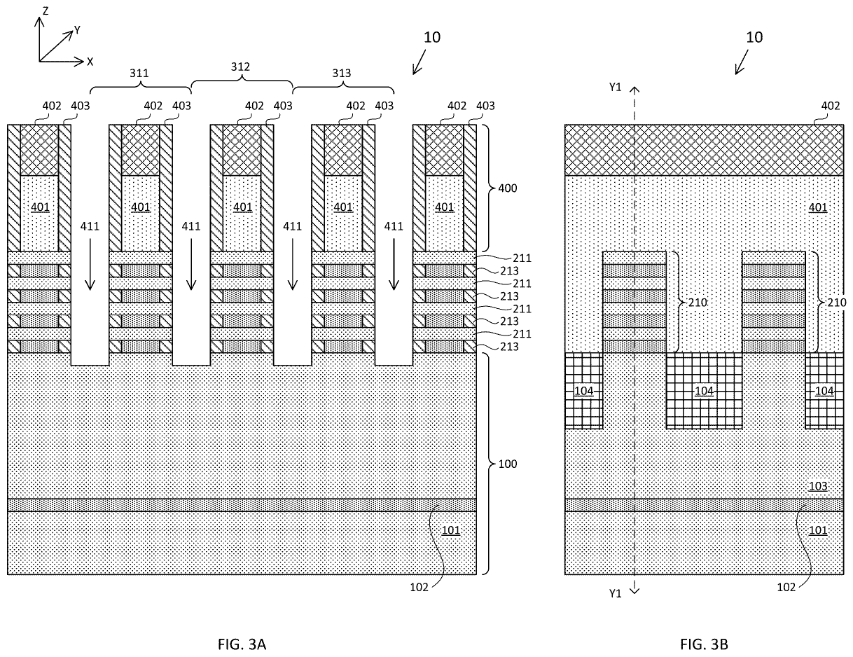

FIGS. 3A and 3B are demonstrative illustrations of different cross-sectional views of a semiconductor structure at a step of manufacturing thereof, following the step illustrated in FIGS. 2A and 2B, according to one embodiment of present invention. More particularly, the one or more stacks of nanosheets 210 may be used to form a plurality or a set of nanosheet (NS) transistors such as a first NS transistor 311, a second NS transistor 312, and a third NS transistor 313. In doing so, embodiments of present invention provide recessing the one or more stacks of nanosheets 210 in source/drain regions of the NS transistors 311, 312, and 313 in a selective etch process using the sacrificial gate structures 400 as an etch mask. The recessing may create a plurality of source/drain (S/D) recesses 411 in the one or more stacks of nanosheets 210, thereby truncating the one or more stacks of nanosheets 210 into a plurality of stacks of nanosheets 210, as is illustrated in FIG. 3A, along the length direction (i.e., x-direction) of the sacrificial gates 401. The plurality of stacks of nanosheets 210 may each include a plurality of Si nanosheets 211 and a plurality of sacrificial layers 212. The S/D recesses 411 may also extend into the Si layer 103 of the semiconductor substrate 100. In one embodiment, a depth of the recesses into the Si layer 103, by the S/D recesses 411, may be comparable with a thickness of the Si nanosheets 211 to be around, for example, 1 to 8 nm.

After creating the S/D recesses 411 by truncating the one or more stacks of nanosheets 210, embodiments of present invention provide performing indentation, through a selective etch process, at end surfaces of the plurality of sacrificial layers 212 to create a plurality of indents, and subsequently filling the plurality of indents with a dielectric material to form a plurality of inner spacers 213. The plurality of inner spacers are at the ends of the sacrificial layers 212, now indented, and vertically between the Si nanosheets 211.

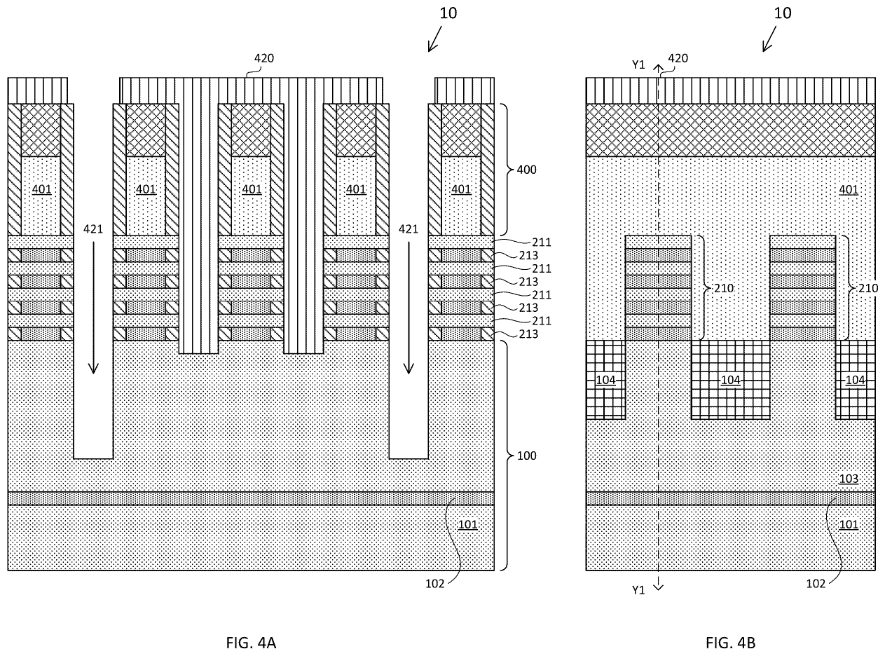

FIGS. 4A and 4B are demonstrative illustrations of different cross-sectional views of a semiconductor structure at a step of manufacturing thereof, following the step illustrated in FIGS. 3A and 3B, according to one embodiment of present invention. More particularly, embodiments of present invention provide covering the semiconductor structure 10, more particularly filling the S/D recesses 411, with an organic planarization (OPL) layer 420. Next, the OPL layer 420 is patterned, through a lithographic patterning and etch process, to remove some of the OPL layer 420 in areas between the sacrificial gates 401 underneath where placeholders are to be formed. Next, one or more placeholder recesses 421 may be created in the Si layer 103 of the semiconductor substrate 100. For example, the one or more placeholder recesses 421 may be formed between the first and the second sacrificial gate 401 and between the fourth and the fifth sacrificial gate 401, as is demonstratively illustrated in FIG. 4A, counting the sacrificial gates 401 from left to right. The placeholder recesses 421 may be created by selectively etching the semiconductor substrate 100, such as the Si layer 103, through the corresponding one or more S/D recesses 411 while rest of the S/D recesses 411 may be protected from the selective etching by the OPL layer 420.

The placeholder recesses 421 may be created by first selectively etching, thereby removing material of the OPL layer 420 in the S/D recesses 411 in areas between the sacrificial gates 401 where placeholder recesses 421 are to be formed. Next, a portion of the Si layer 103 exposed by the removal of material of the OPL layer 420 may be etched and removed through a selective and directional etch process. Being covered by the sacrificial gates 401, the selective and directional etch process may not affect the plurality of Si nanosheets 211.

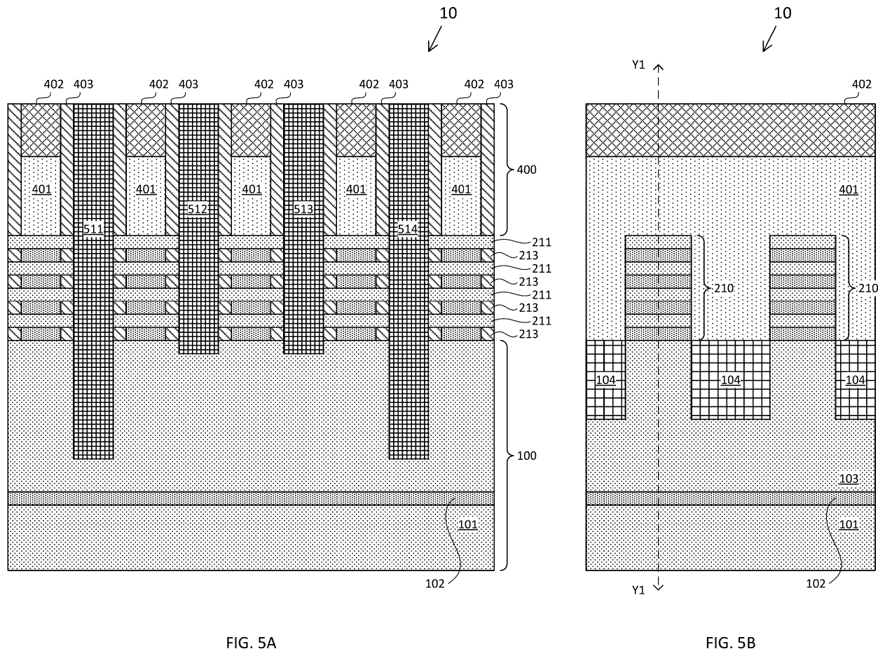

FIGS. 5A and 5B are demonstrative illustrations of different cross-sectional views of a semiconductor structure at a step of manufacturing thereof, following the step illustrated in FIGS. 4A and 4B, according to one embodiment of present invention. More particularly, embodiments of present invention provide removing remaining portions of the OPL layer 420, particularly material of the OPL layer 420 between the sacrificial gates 401 to re-expose the rest of the S/D recesses 411, in addition to those already exposed in the creation of the one or more placeholder recesses 421.

Next, a first dielectric material or materials suitable for forming placeholders may be deposited in the S/D recesses 411 and in the placeholder recesses 421. The first dielectric material may be, for example, silicon-carbide (SiC), aluminum-oxide (AlOx), and/or aluminum-nitride (AlN), and the deposition may be made through a chemical-vapor-deposition (CVD) process, a physical-vapor-deposition (PVD) process, an atomic-layer-deposition (ALD) process or other suitable processes. The deposition of the first dielectric material may thereby form a first dielectric layer, which may include a plurality of sacrificial pillars such as first, second, third, and fourth sacrificial pillars 511, 512, 513, and 514. Lower portions of some of the sacrificial pillars, such as the first and the fourth sacrificial pillar 511 and 514, may be formed into placeholders later. A chemical-mechanical-polishing (CMP) process may be applied to planarize the first dielectric layer including top surfaces of the first, second, third, and fourth sacrificial pillars 511, 512, 513, and 514.

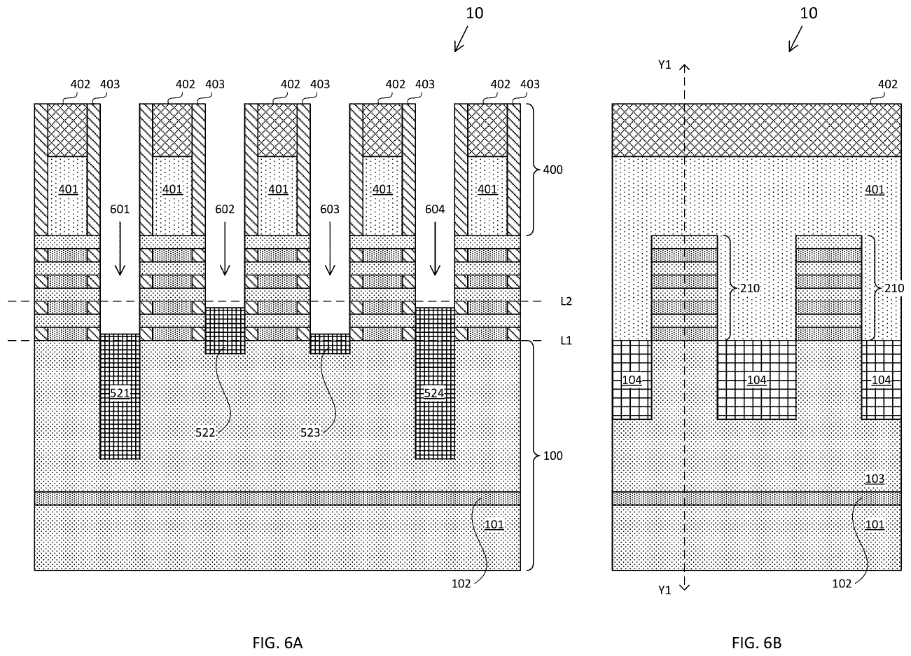

FIGS. 6A and 6B are demonstrative illustrations of different cross-sectional views of a semiconductor structure at a step of manufacturing thereof, following the step illustrated in FIGS. 5A and 5B, according to one embodiment of present invention. More particularly, embodiments of present invention provide recessing the first dielectric layer by recessing the plurality of sacrificial pillars including the first, second, third, and fourth sacrificial pillars 511, 512, 513, and 514. The recessing thus creates a recessed first dielectric layer which includes first, second, third, and fourth recessed sacrificial pillars 521, 522, 523, and 524, and creates a plurality of recesses such as first, second, third, and fourth recesses 601, 602, 603, and 604 on top of the recessed first dielectric layer. In one embodiment, because of process variations such as variation in the gap, distance, and/or width of the S/D recesses 411 between two neighboring sacrificial gates 401, center-to-edge non-uniformity, and/or die-to-die variation, the recesses 601, 602, 603, and 604 may have certain variation such as variation in depths. According to one embodiment of present invention, the semiconductor structure 10 including the NS transistors 311, 312, and 313 formed later may be immune, to certain extent, to this depth variation, particularly when this depth variation is within a certain range as being explained below in more details.

For example, the recessed first dielectric layer of the first, second, third, and fourth recessed sacrificial pillars 521, 522, 523, and 524 may have their respective heights that fall within a certain range such as above a first height level L1 and below a second height level L2. According to one embodiment, the first height level L1 may be at a level of the top surface of the Si layer 103 or the semiconductor substrate 100 and the second height level L2 may be at a level of the bottom of a reference Si nanosheet. The reference Si nanosheet is the second Si nanosheet from a bottom of the plurality of Si nanosheets 211. For example, as being demonstratively illustrated in FIG. 6A, heights of the first and the third recessed sacrificial pillar 521 and 523 are above the first height level L1 but below the first Si nanosheet therefore below the second height level L2; and heights of the second and the fourth recessed sacrificial pillar 522 and 524 are above the first height level L1 and the first Si nanosheet but below the second Si nanosheet which is the reference Si nanosheet. Performance of the NS transistors 311, 312, and 313 of the semiconductor structure 10 are, to certain extent, immune to these height variations, as being explained more clearly in the below description. The first and fourth recessed sacrificial pillars 521 and 524 form one or more placeholders. The second and third recessed sacrificial pillars 522 and 523 may be residual of the first dielectric layer of the first dielectric material. In other words, the recessed first dielectric layer may have a height between L1 and L2.

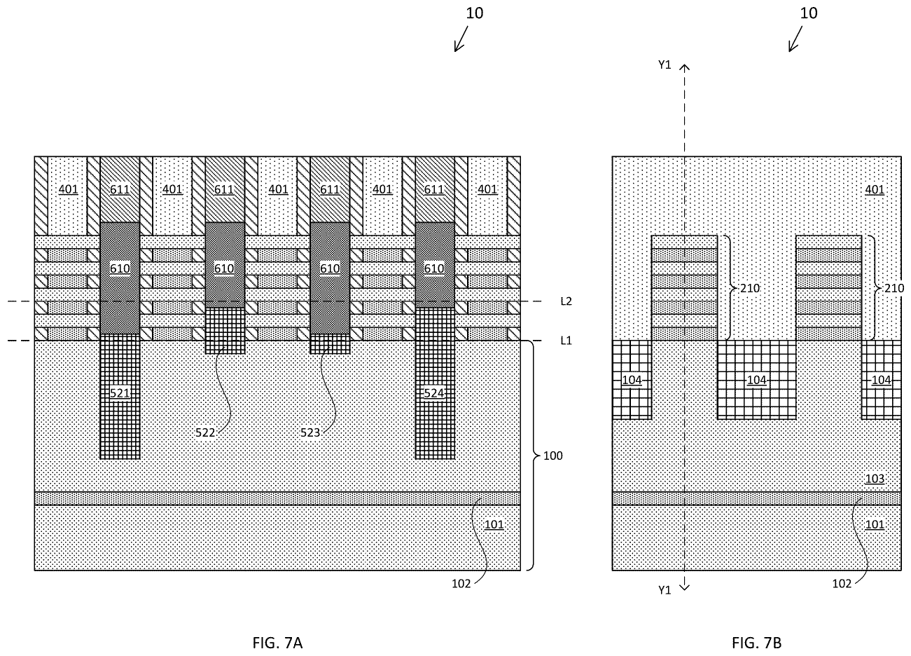

FIGS. 7A and 7B are demonstrative illustrations of different cross-sectional views of a semiconductor structure at a step of manufacturing thereof, following the step illustrated in FIGS. 6A and 6B, according to one embodiment of present invention. More particularly, embodiments of present invention provide forming source/drain (S/D) regions 610 of the NS transistors 311, 312, and 313 by epitaxially growing, for example, P+ epi SiGe:B or N+ epi Si:P depending on the type of the NS transistors 311, 312, and 313 to be formed, from exposed end or sidewall surfaces of the Si nanosheets 211. The S/D regions 610 may be formed above the recessed first dielectric layer of the first, second, third, and fourth recessed sacrificial pillars 521, 522, 523, and 524. Because the S/D regions 610 grow epitaxially from the end or sidewall surfaces of the Si nanosheets 211, top surfaces of the S/D regions 610 may be substantially coplanar with each other and independent from depths of the recesses 601, 602, 603, and 604.

After forming the epitaxial S/D regions 610, a dielectric capping layer 611 may be formed, for example through deposition, on top of the S/D regions 610. Next, the dielectric capping layer 611 may be planarized through, for example, a CMP process. The CMP process may subsequently remove the capping layers 402 above the sacrificial gates 401. The dielectric capping layer 611 may become coplanar with top surfaces of the sacrificial gates 401.

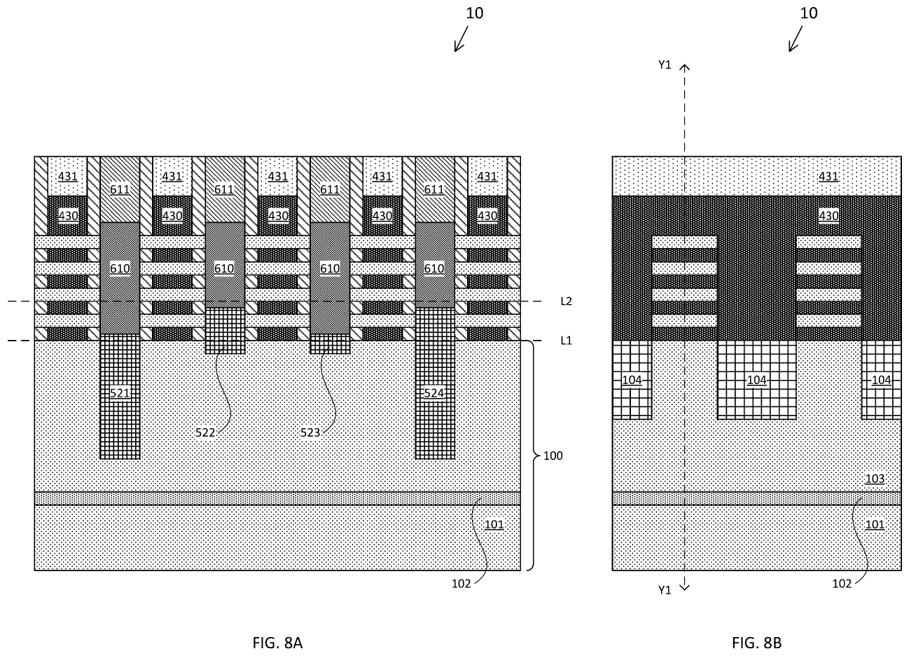

FIGS. 8A and 8B are demonstrative illustrations of different cross-sectional views of a semiconductor structure at a step of manufacturing thereof, following the step illustrated in FIGS. 7A and 7B, according to one embodiment of present invention. More particularly, embodiments of present invention provide performing a replacement-metal-gate (RMG) process to form a plurality of metal gates 430 that surrounds the plurality of Si nanosheets 211. More particularly, the sacrificial gates 401 may first be selectively removed in a selective etch process and the plurality of sacrificial layers 212, exposed by the removal of the sacrificial gates 401, may next be removed to expose a central portion of the plurality of Si nanosheets 211. A gate dielectric layer may then be deposited to surround the central portion of the plurality of Si nanosheets 211; one or more work-function metal (WFM) layers may be deposited on top of the gate dielectric layer; and a conductive material may be deposited on top of the one or more WFM layers thereby forming the plurality of metal gates 430.

Subsequently, a CMP process may be applied to planarize a top surface of the plurality of metal gates 410. The plurality of metal gates 410 may then be recessed to create recesses between the dielectric capping layers 611. A gate capping layer 431 may next be formed in the recesses to protect the plurality of metal gates 430.

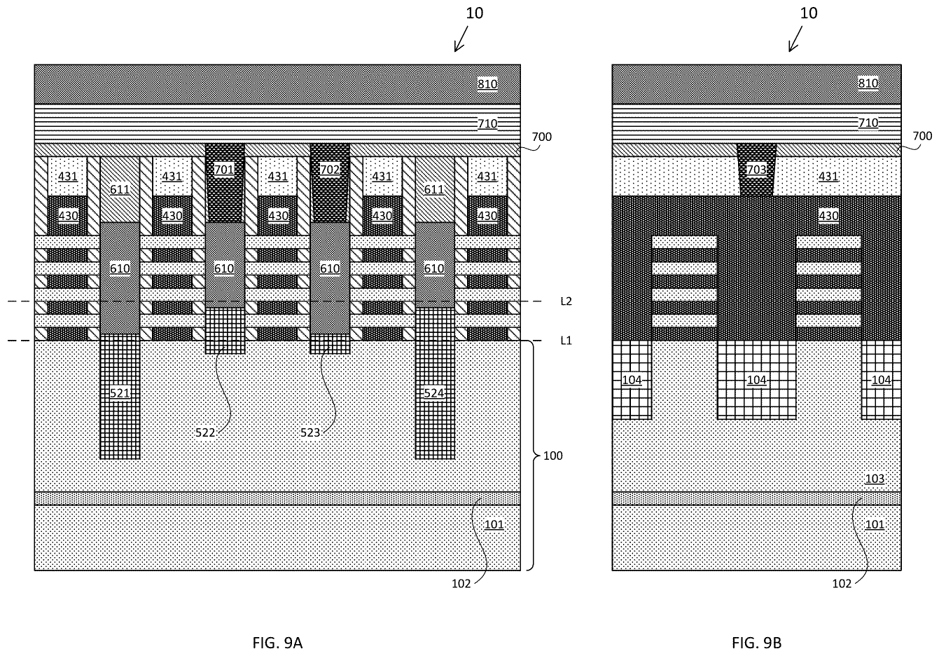

FIGS. 9A and 9B are demonstrative illustrations of different cross-sectional views of a semiconductor structure at a step of manufacturing thereof, following the step illustrated in FIGS. 8A and 8B, according to one embodiment of present invention. More particularly, embodiments of present invention provide forming additional dielectric layer or layers, such as an interlevel-dielectric (ILD) layer 700, on top of the plurality of metal gates 430 via the gate capping layer 431 and on top of the dielectric capping layer 611; forming one or more frontside S/D contacts such as frontside S/D contacts 701 and 702 in contact with the S/D regions 610 through the ILD layer 700 and the dielectric capping layer 611; and forming one or more gate contacts such as a gate contact 703 in contact with the gate 430 through the ILD layer 700 and the gate capping layer 431.

Embodiments of present invention further provide forming a back-end-of-line (BEOL) interconnect structure 710 on top of the ILD layer 700. The BEOL interconnect structure 710 may provide signal routing, power supply, and other interconnect functions to the NS transistors 311, 312, and 313 through the one or more frontside S/D contacts 701 and 702 and the gate contact 703.

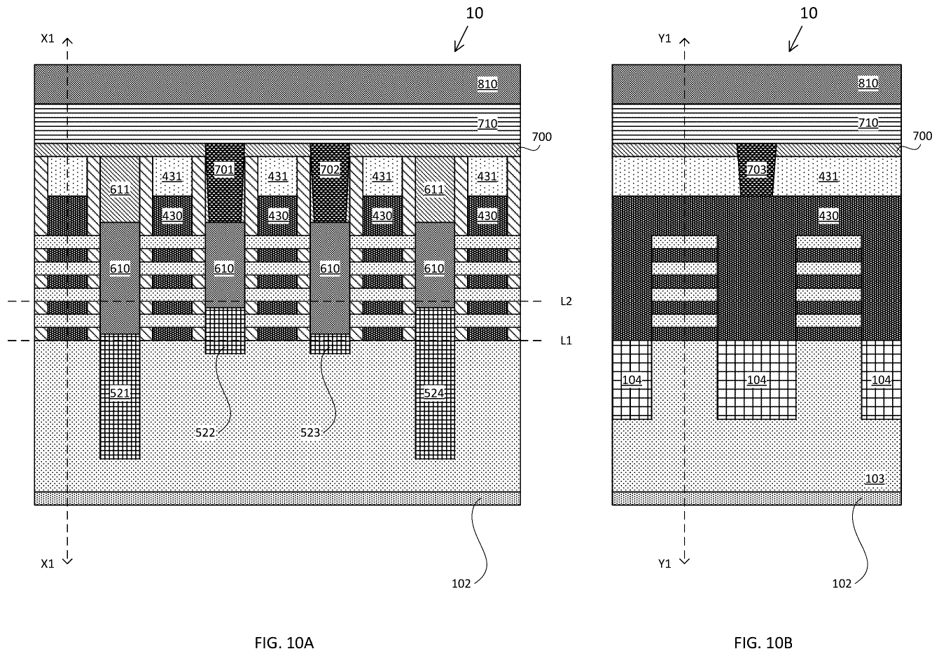

After forming the BEOL interconnect structure 710, a handling wafer 810 may be attached, for example through a bonding process, to the BEOL interconnect structure 710 such as the semiconductor structure 10 may be flipped upside-down for processing from the backside of the semiconductor substrate 100. Hereinafter, although various processes may be applied from the backside of the semiconductor structure 10, for the ease of illustration, FIGS. 10A and 10B to FIGS. 17A and 17B will continue to be demonstratively illustrated upside-up and described according to that illustration.

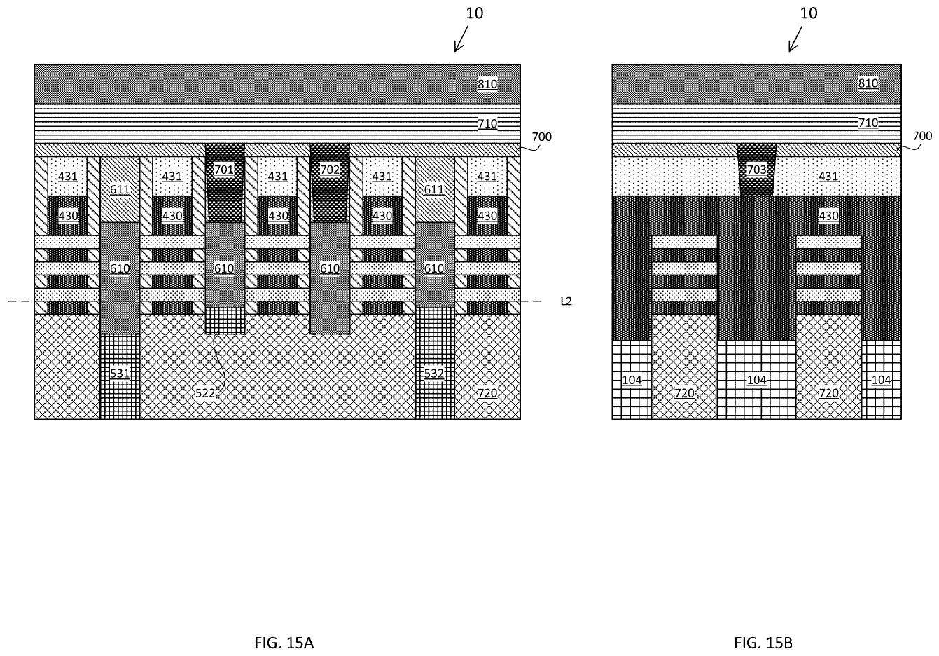

FIGS. 10A and 10B are demonstrative illustrations of different cross-sectional views of a semiconductor structure at a step of manufacturing thereof, following the step illustrated in FIGS. 9A and 9B, according to one embodiment of present invention. More particularly, embodiments of present invention provide replacing the substate 100 with a backside interlevel dielectric (BILD) layer 720 (see FIGS. 15A and 15B). In doing so, embodiments of present invention provide first removing the bulk Si substrate 101 through, for example, a CMP process, a grinding process, and/or other selective etch processes to stop at the dielectric layer 102. The dielectric layer 102 serves as an etch-stop-layer thereby easing the controlling of the etch process.

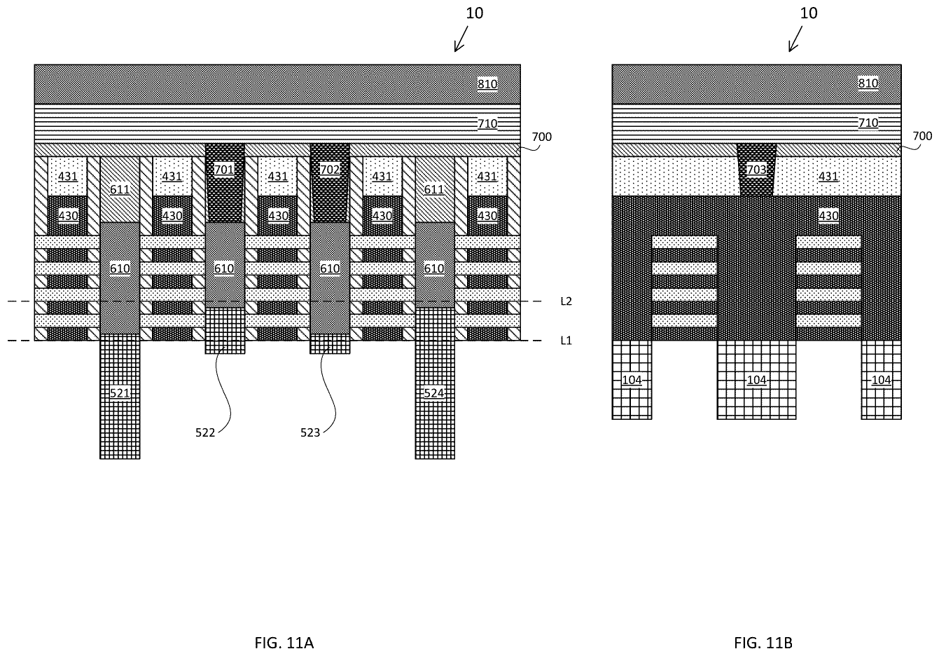

FIGS. 11A and 11B are demonstrative illustrations of different cross-sectional views of a semiconductor structure at a step of manufacturing thereof, following the step illustrated in FIGS. 10A and 10B, according to one embodiment of present invention. More particularly, embodiments of present invention provide continuing to remove the dielectric layer 102 selectively to expose the Si layer 103; and removing the Si layer 103. The Si layer 103 may be selectively removed to expose the first, second, third, and fourth recessed sacrificial pillars 521, 522, 523, and 524 and expose the one or more STI layers 104 while the S/D regions 610 are protected by the first, second, third, and fourth recessed sacrificial pillars 521, 522, 523, and 524. As being described below in more details, the first and the fourth recessed sacrificial pillars 521 and 524, previously formed in the placeholder recesses 421 (see FIG. 4A), may serve as placeholders for forming backside contacts. The second and third recessed sacrificial pillars 522 and 523 may be residual portions of the sacrificial pillars 512 and 513, some of which may be optionally removed later.

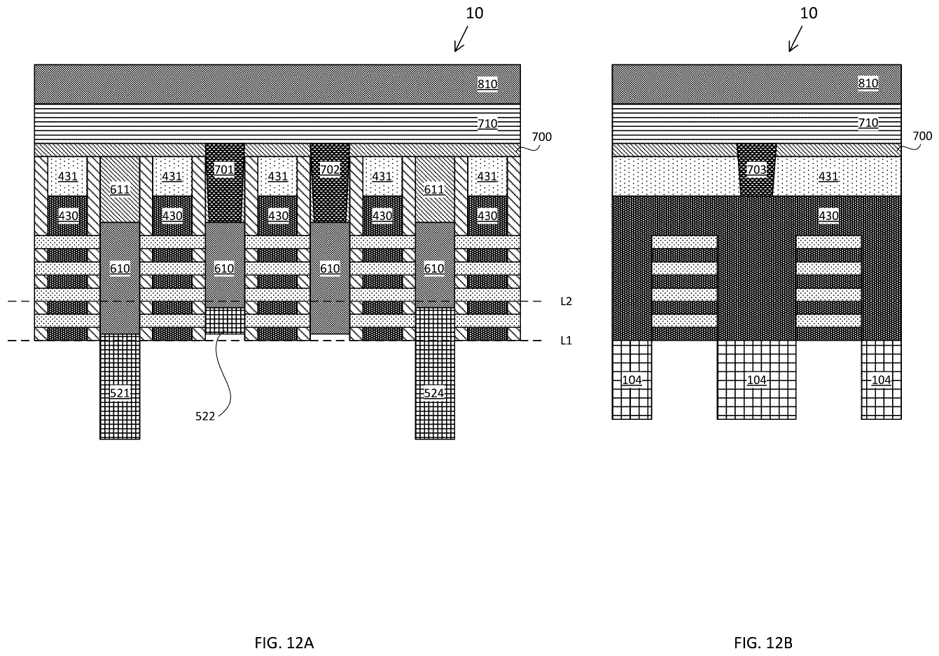

FIGS. 12A and 12B are demonstrative illustrations of different cross-sectional views of a semiconductor structure at a step of manufacturing thereof, following the step illustrated in FIGS. 11A and 11B, according to one embodiment of present invention. More particularly, embodiments of present invention provide, optionally, etching the first, second, third, and fourth recessed sacrificial pillars 521, 522, 523, and 524 selectively, relative to the other exposed structures such as the metal gates 430, the inner spacers 213, and the STI layers 104. The selective etching process, such as a RIE process, may remove completely the third recessed sacrificial pillar 523 which has a smallest height when compared with the first, second, and fourth recessed sacrificial pillars 521, 522, and 524. Heights of the first, second, and fourth recessed sacrificial pillars 521, 522, and 524 may be correspondingly shortened as well. The removal of the third recessed sacrificial pillar 523 helps reduce parasitic capacitance of the semiconductor structure 10.

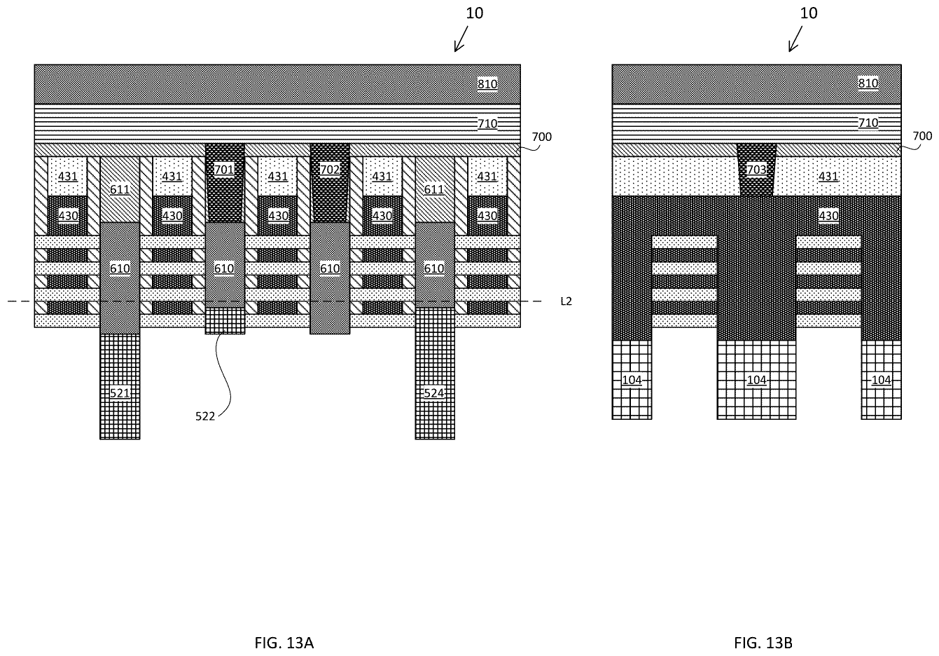

FIGS. 13A and 13B are demonstrative illustrations of different cross-sectional views of a semiconductor structure at a step of manufacturing thereof, following the step illustrated in FIGS. 12A and 12B, according to one embodiment of present invention. More particularly, embodiments of present invention provide selectively etching the exposed portion of the metal gates 430 that is underneath the first Si nanosheet 211, i.e., the bottom-most Si nanosheet 211 of the plurality of Si nanosheets 211. More particularly, the one or more WFM layers of the metal gate 430 and the gate dielectric layer of high-k material, such as HfO₂, surrounding the bottom-most Si nanosheet 211 may be selectively etched away or removed. In the meantime, the exposed inner spacers 213 underneath the bottom-most Si nanosheet 211 may be selectively removed as well. The inner spacers 213 may include a dielectric material having an etch selectivity that is different from that of the first, second, and fourth sacrificial pillars 521, 522, and 524 and thus may be selectively removed.

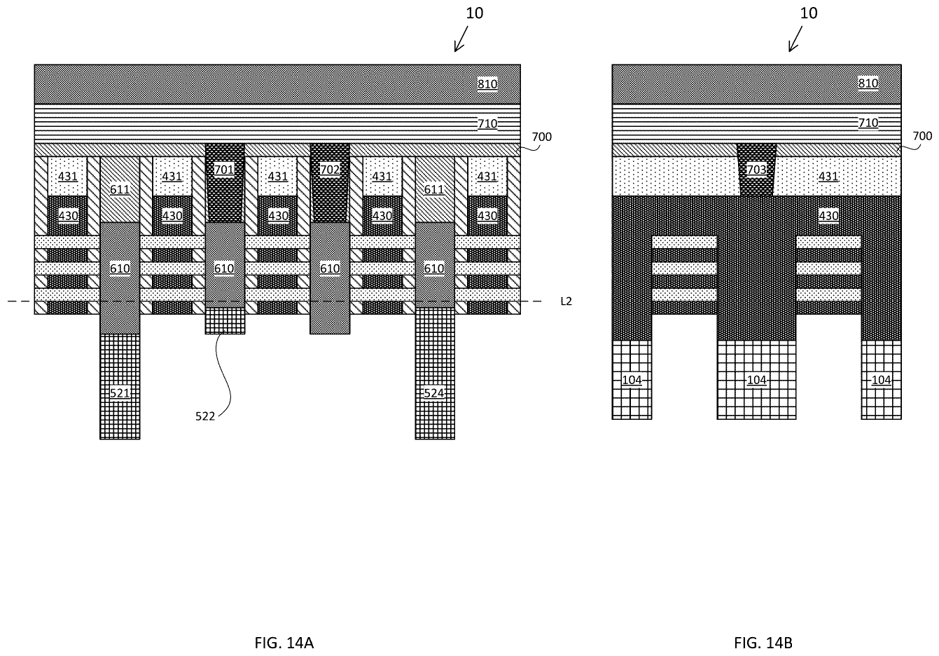

FIGS. 14A and 14B are demonstrative illustrations of different cross-sectional views of a semiconductor structure at a step of manufacturing thereof, following the step illustrated in FIGS. 13A and 13B, according to one embodiment of present invention. More particularly, embodiments of present invention provide selectively removing the exposed the first Si nanosheet 211, i.e., the bottom-most Si nanosheet 211. The bottom-most Si nanosheet 211 may be removed through a RIE process that is selective relative to the materials of the S/D region 610, the inner spacers 213, the first, second, and fourth recessed sacrificial pillars 521, 522, and 524, and the STI layers 104.

By removing the bottom-most Si nanosheet 211 of the plurality of Si nanosheets 211, embodiments of present invention ensures that variation in height of the first, second, third, and fourth recessed sacrificial pillars 521, 522, 523, and 524 does not cause any difference in the number of Si nanosheets used in forming NS transistors, such as the NS transistors 311, 312, and 313 of the semiconductor structure 10. For example, in the demonstratively illustrated FIG. 14A, the three NS transistors 311, 312, and 313 all employ three Si nanosheets regardless some of the S/D regions 610 may be initially formed in contact with the bottom-most Si nanosheet 211.

FIGS. 15A and 15B are demonstrative illustrations of different cross-sectional views of a semiconductor structure at a step of manufacturing thereof, following the step illustrated in FIGS. 14A and 14B, according to one embodiment of present invention. More particularly, embodiments of present invention provide depositing a backside interlevel dielectric (BILD) layer 720 of a second dielectric material, for example through a CVD process, a PVD process, or an ALD process to cover the first and fourth recessed sacrificial pillars 521 and 524, which may be referred to and demonstratively illustrated in FIG. 15A as placeholders 531 and 532 for forming backside contacts. The second dielectric material may include, for example, SiC, AlOx, SiCNO, SiOx, AlN and may be different from the first dielectric material that forms the placeholders 531 and 532. The BILD layer 720 may also cover other exposed backside areas such as the metal gates 430, some of the S/D regions 610, as well as the residual portion of the second sacrificial pillar 522. A CMP process may subsequently be applied to planarize a top surface of the BILD layer 720, illustrated in FIG. 15A as a bottom surface of the BILD layer 720. The CMP process may expose the placeholders 531 and 532 for further processing.

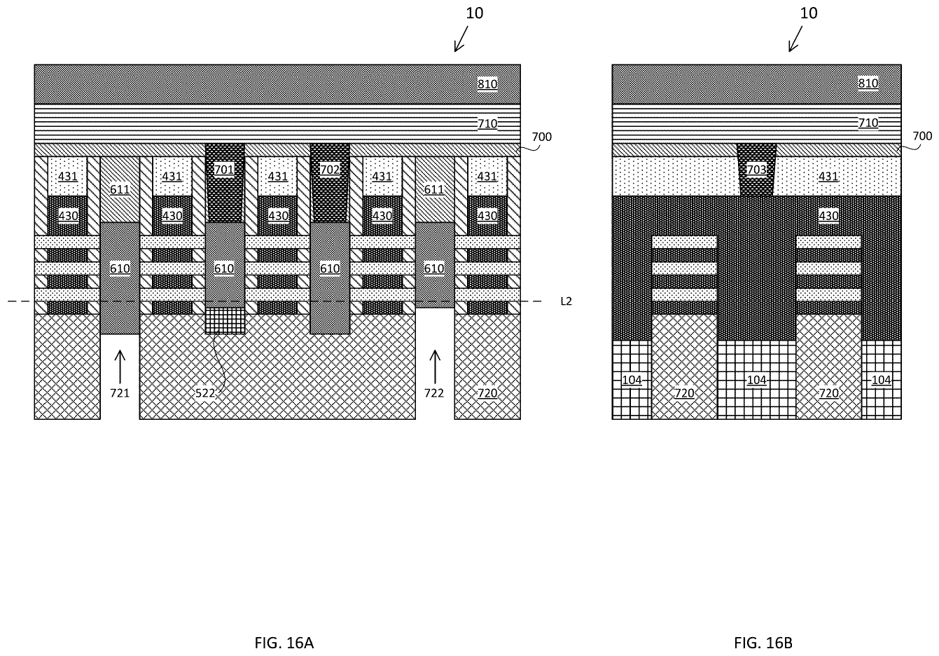

FIGS. 16A and 16B are demonstrative illustrations of different cross-sectional views of a semiconductor structure at a step of manufacturing thereof, following the step illustrated in FIGS. 15A and 15B, according to one embodiment of present invention. More particularly, embodiments of present invention provide replacing the placeholders 531 and 532 with one or more backside conducts. In doing so, embodiments of present invention provide selectively removing placeholders 531 and 532 from the BILD layer 720 thereby creating openings 721 and 722 in the BILD layer 720. The openings 721 and 722 may expose bottom surfaces of some of the S/D regions 610 of their respective NS transistors 311, 312, and 313, that were originally above the placeholders 531 and 532.

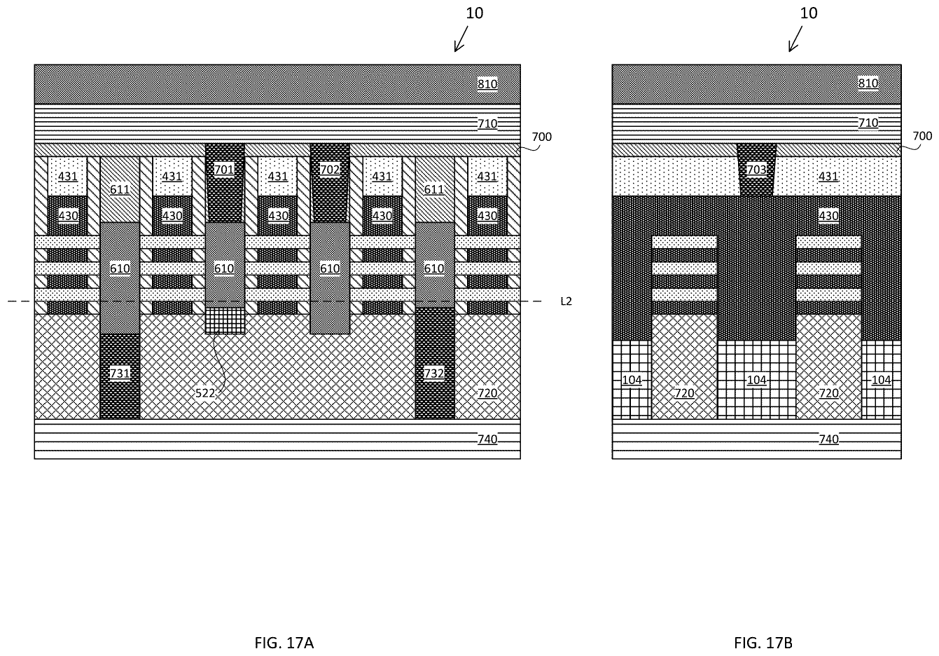

FIGS. 17A and 17B are demonstrative illustrations of different cross-sectional views of a semiconductor structure at a step of manufacturing thereof, following the step illustrated in FIGS. 16A and 16B, according to one embodiment of present invention. More particularly, embodiments of present invention provide filling the openings 721 and 722, which are spaces left by the selectively removing placeholders 531 and 532, with a conductive material to form a first and a second backside contact 731 and 732. Although the first backside contact 731 and the second backside contact 732 may have different heights, the S/D regions 610 in contact with the first and the second backside contact 731 and 732 all horizontally contact three Si nanosheets of the plurality of Si nanosheets 210.

After forming the backside contacts 731 and 732, embodiments of present invention provide forming a backside BEOL structure 740 next to the BILD layer 720 and the backside contacts 731 and 732. The backside BEOL structure 740 provides signal routing and/or power supply functions to the NS transistors 311, 312, and 313.

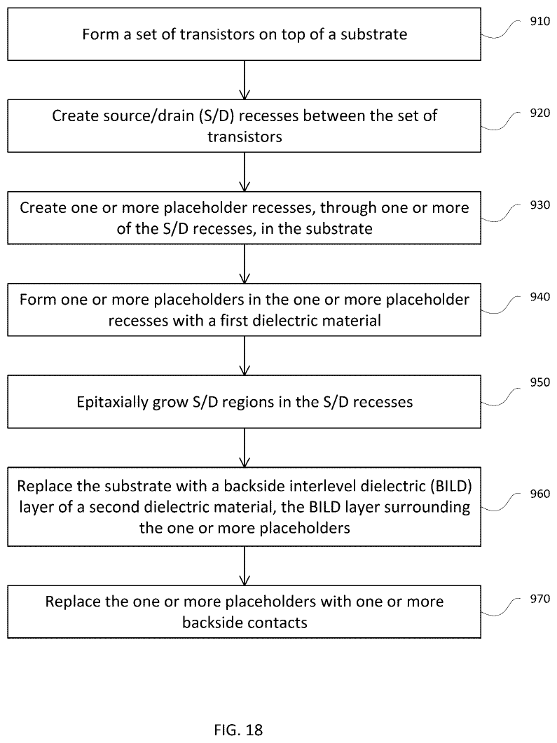

FIG. 18 is a demonstrative illustration of a flow-chart of a method of manufacturing a semiconductor structure according to embodiments of present invention. The method includes a step at (910) of forming a set of transistors on top of a substrate; a step at (920) of creating source/drain (S/D) recesses between the set of transistors; a step at (930) of creating one or more placeholder recesses, through one or more of the S/D recesses, in the substrate; a step at (940) of forming one or more placeholders in the one or more placeholder recesses with a first dielectric material; a step at (950 of epitaxially growing S/D regions in the S/D recesses; a step at (960) of replacing the substrate with a backside interlevel dielectric (BILD) layer of a second dielectric material, the BILD layer surrounding the one or more placeholders; and a step at (970) of replacing the one or more placeholders with one or more backside contacts.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A method comprising:
forming a set of transistors on top of a substrate;
creating source/drain (S/D) recesses between the set of transistors;
creating one or more placeholder recesses, through one or more of the S/D recesses, in the substrate;
forming one or more placeholders in the one or more placeholder recesses with a first dielectric material;
epitaxially growing S/D regions in the S/D recesses;
replacing the substrate with a backside interlevel dielectric (BILD) layer of a second dielectric material, the BILD layer surrounding the one or more placeholders; and
replacing the one or more placeholders with one or more backside contacts.

2. The method of claim 1, wherein forming the one or more placeholders comprises:
depositing the first dielectric material in the one or more placeholder recesses, in the S/D recesses, and on top of the set of transistors to form a first dielectric layer;
planarizing the first dielectric layer; and
recessing the first dielectric layer between the set of transistors to form the one or more placeholders.

3. The method of claim 2, wherein the set of transistors is a set of nanosheet transistors with each of the set of nanosheet transistors having a set of nanosheets, wherein depositing the first dielectric material comprises forming the first dielectric layer in direct contact with sidewalls of the set of nanosheets of each of the set of nanosheet transistors.

4. The method of claim 3, wherein forming the one or more placeholders further comprises recessing the first dielectric layer until a top surface of the first dielectric layer is below a second nanosheet from a bottom of the set of nanosheets.

5. The method of claim 4, wherein recessing the first dielectric layer causes a portion of the first dielectric material remaining directly on top of the substrate without any of the one or more placeholder recesses underneath thereof.

6. The method of claim 1, wherein creating the one or more placeholder recesses comprises performing a selective etch process to etch the substrate through the one or more of the S/D recesses while rest of the S/D recesses are protected from the selective etch process.

7. The method of claim 1, wherein replacing the one or more placeholders comprises:
selectively etching the first dielectric material, relative to the second dielectric material, to remove the one or more placeholders until one or more of the S/D regions above the one or more placeholders are exposed; and
filling spaces left by the selectively etching the first dielectric material with a conductive material to form the one or more backside contacts,
wherein the first dielectric material is different from the second dielectric material in etch selectivity.

8. The method of claim 1, wherein replacing the substrate comprises:
selectively removing the substrate, relative to the first dielectric material of the one or more placeholders, until gate metal of the set of transistors are exposed; and
selectively etching the first dielectric material, relative to the gate metal of the set of transistors, until a bottom surface of at least one of the S/D regions is exposed.

9. The method of claim 8, wherein the set of transistors is a set of nanosheet transistors with each of the set of nanosheet transistors having a set of nanosheets, and wherein replacing the substrate further comprises:
selectively etching the exposed gate metal of the set of nanosheet transistors, relative to the exposed at least one of the S/D regions, until a bottom nanosheet of the set of nanosheets is exposed;
selectively removing the bottom nanosheet; and
depositing the second dielectric material to form the BILD layer to surround the one or more placeholders.

10. A method comprising:
forming a set of nanosheet transistors on top of a substrate with each of the set of nanosheet transistors having a set of nanosheets;
creating source/drain (S/D) recesses between the set of nanosheet transistors to expose sidewalls of the set of nanosheets;
creating one or more placeholder recesses, through one or more of the S/D recesses, in the substrate;
forming one or more placeholders in the one or more placeholder recesses with a first dielectric material;
epitaxially growing S/D regions in the S/D recesses;
replacing the substrate with a backside interlevel dielectric (BILD) layer of a second dielectric material, the BILD layer surrounding the one or more placeholders; and
replacing the one or more placeholders with one or more backside contacts.

11. The method of claim 10, wherein forming the one or more placeholders comprises:
depositing the first dielectric material in the one or more placeholder recesses, in the S/D recesses, and on top of the set of nanosheet transistors to form a first dielectric layer, the first dielectric layer in direct contact with the sidewalls of the set of nanosheets;
planarizing the first dielectric layer; and
recessing the first dielectric layer between the set of nanosheet transistors to form the one or more placeholders.

12. The method of claim 11, wherein forming the one or more placeholders further comprises recessing the first dielectric layer until a top surface of the first dielectric layer is below a second nanosheet from a bottom of the set of nanosheets.

13. The method of claim 12, wherein recessing the first dielectric layer causes a portion of the first dielectric material remaining directly on top of the substrate without any of the one or more placeholder recesses underneath thereof.

14. The method of claim 10, wherein creating the one or more placeholder recesses comprises performing a selective etch process to etch the substrate through the one or more of the S/D recesses while rest of the S/D recesses are protected from the selective etch process.

15. The method of claim 10, wherein replacing the one or more placeholders comprises:
selectively etching the first dielectric material, relative to the second dielectric material, to remove the one or more placeholders until one or more of the S/D regions above the one or more placeholders are exposed; and
filling spaces left by the selectively etching the first dielectric material with a conductive material to form the one or more backside contacts,
wherein the first dielectric material is different from the second dielectric material in etch selectivity.

16. The method of claim 10, wherein replacing the substrate comprises:
selectively removing the substrate, relative to the first dielectric material of the one or more placeholders, until gate metal of the set of nanosheet transistors are exposed; and
selectively etching the first dielectric material, relative to the gate metal of the set of nanosheet transistors, until a bottom surface of at least one of the S/D regions is exposed.

17. The method of claim 16, wherein replacing the substrate further comprises:
selectively etching the exposed gate metal of the set of nanosheet transistors, relative to the exposed at least one of the S/D regions, until a bottom nanosheet of the set of nanosheets is exposed;
selectively removing the bottom nanosheet; and
depositing the second dielectric material to form the BILD layer to surround the one or more placeholders.

18. A semiconductor structure comprising:
a set of nanosheet transistors on top of a substrate, each of the set of nanosheet transistors having a set of nanosheets, a metal gate surrounding the set of nanosheets, and source/drain regions at sidewalls of the set of nanosheets;
one or more backside contacts underneath one or more of the source/drain regions of the set of nanosheet transistors, the backside contacts being surrounded by a backside interlevel dielectric (BILD) layer of a second dielectric material; and
a first dielectric layer of a first dielectric material between one of the source/drain regions of the set of nanosheet transistors and the BILD layer, the first dielectric material being different from the second dielectric material.

19. The semiconductor structure of claim 18, wherein one or more of the source/drain regions have a bottom surface that is below a bottom surface of the metal gate and wherein one of the one or more backside contacts has a top surface that is above the bottom surface of the metal gate.

20. The semiconductor structure of claim 18, wherein one or more of the source/drain regions have a bottom surface that is above a bottom surface of the metal gate and wherein one of the one or more backside contacts has a top surface that is below the bottom surface of the metal gate.
